(19) United States
(12) Patent Application Publication
(10) Pub. No.: US 2026/0309567 A1
(43) Pub. Date: Oct. 8, 2026

(54) SENSOR SYSTEM AND METHOD FOR VERIFYING THE SAFETY INTEGRITY OF A SENSOR SYSTEM

(71) Applicant: Pilz GmbH & Co. KG, Ostfildern (DE)

(72) Inventors: Lambertus Pieter MONNEE, Ostfildern (DE); Armin GLASER, Ostfildern (DE)

(21) Appl. No.: 19/642,091

(22) Filed: Apr. 8, 2026

(30) Foreign Application Priority Data
Apr. 8, 2025 (DE) 10 2025 113 847.8

(51) Int. Cl. G01L 27/00; G01L 9/04

(52) U.S. Cl. CPC G01L 27/007; G01L 9/04

(57) ABSTRACT

A sensor system includes two analog sensors, each including a resistive sensing device that measures a physical variable and a Wheatstone bridge that generate an analog voltage signal in response to the physical variable. Each of the analog sensors supplies a measurement signal to a safety controller based on their respective analog voltage signals. The resistive sensing device of each analog sensor is connected to a switching path having parallel working and test paths with different resistances. The safety controller activates the test paths to alternately test the two resistive sensing devices and checks the plausibility of signal deviations in the measurement signals resulting from the tests.

### CROSS REFERENCE TO RELATED APPLICATIONS

This application claims priority under 35 U.S.C. § 119(a)-(d) to German patent application No. 10 2025 113 847.8, filed on Apr. 8, 2025, the entire contents of which are hereby incorporated by reference.

### TECHNICAL FIELD

The present disclosure relates to a sensor system having at least two analog sensors and to a method for checking a safety integrity of a sensor system.

### BACKGROUND

Sensor systems with analog sensors are often used in process-related areas to detect, for example, pressures, temperatures, or leakages. For reasons of measurement redundancy, such sensor systems have at least two single-channel analog sensors, in particular in safety-critical applications.

One possible area of application for sensor systems with analog sensors is hydrogen technology, which has become increasingly important in recent years. Thus, from the point of view of functional safety, it is necessary to record the pressures prevailing during hydrogen production, hydrogen transport, and hydrogen storage and possible leakages in the hydrogen tanks, piping systems, and other fluid-carrying or fluid-distributing equipment used. The same applies to filling stations where fuel cell vehicles are refueled with hydrogen.

The analog sensors used for pressure measurement are based on a measurement principle in which at least one resistive analog sensing device, in particular a strain gauge, is used to detect pressures or pressure changes. A strain gauge is sensitive to tension and compression and thus changes its electrical resistance. The resistive analog sensing device, in particular the strain gauge, converts the physical measured variable "pressure" into an electrical signal that varies proportionally to it. In addition to the resistive sensing device, an analog sensor for detecting pressure typically comprises a pressure-resistant base body and a thin membrane, to which the resistive sensing device, in particular the strain gauge, is attached. Under the effect of pressure, the membrane deforms reversibly. This stretches or compresses the resistive analog sensing device, in particular the strain gauge, so that the electrical resistance changes. This change in resistance is directly proportional to the pressure. The resistive sensing device is part of a Wheatstone bridge, the electrical signal of which can be tapped and evaluated. One problem with such sensor systems is that they use non-safe analog sensors.

### SUMMARY

An object is to provide a sensor system having at least two analog sensors and a method for checking the safety integrity of such a sensor system, which enables safe evaluation of the non-safe analog sensors.

A sensor system according to the disclosure comprises:
a first analog sensor having at least one first resistive sensing device configured to measure a physical variable, and including a first sensing device comprising a Wheatstone bridge and designed to generate a first analog voltage signal that forms a measurement signal of the first analog sensor or from which the measurement signal of the first analog sensor can be generated by measurement signal conversion, wherein the first sensing device is connected to a first switching path, which comprises a working path and a test path which is connected in parallel with the working path and has resistance characteristics that are different from those of the working path,
a second analog sensor having at least one second resistive sensing device configured to measure a physical variable, and including a second sensing device comprising a second Wheatstone bridge and designed to generate a second analog voltage signal that forms a measurement signal of the second analog sensor or from which the measurement signal of the second analog sensor can be generated by measurement signal conversion, wherein the second sensing device is connected to a second switching path, which comprises a working path and a test path which is connected in parallel with the working path and has resistance characteristics that are different from those of the working path,
a safety controller which is connected to the analog sensors, wherein the safety controller is designed to:
   a) receive and evaluate the measurement signals of the first analog sensor and of the second analog sensor,
   b) activate the test path of the first switching path to test the first sensing device, generate a first test signal and detect a signal deviation of the measurement signal of the first analog sensor,
   c) test the second sensing device, to activate the test path of the second switching path, to generate a second test signal and to detect a signal deviation of the measurement signal of the second analog sensor, and
   d) check the plausibility of the signal deviation of the measurement signals of the analog sensors.

By testing the sensing devices, the sensor system according to the disclosure enables a safe evaluation of non-safe analog sensors in an advantageous way and can be used in very different process-related areas, for example, to detect pressures, temperatures, or leakages. The test signal is preferably selected such that it has a high level (e.g., + 24 V) and a low level (e.g., 0 V). While one of the two analog sensors is being tested, the Wheatstone bridge of the respective analog sensor is detuned. As a result, an increased or decreased signal deviation is generated in the time interval in which the respective test signal has a high level. If the physical variable to be measured in the system to be monitored has a certain numerical value, each of the two analog sensors outputs a certain analog measurement signal corresponding to this numerical value during normal operation, in which no test takes place. When testing the sensing devices, different resistances in the test paths of the sensing devices lead to an increase or decrease in resistance, resulting in a negative signal deviation or a positive signal deviation compared to normal operation. The magnitude of the signal deviation depends on the resistors used in the switching paths. The corresponding signal deviations can be calculated accordingly from the measurement signals. The expectation of the safety controller is that the analog measurement signals, which are in particular current signals or voltage signals, must change by a defined value within a defined time interval while the test of the respective analog sensor is performed. This allows the analog measurement signals of the analog sensors to be checked for plausibility so that the safety integrity of the analog sensors can also be tested. In other words, the sensor system according to the disclosure enables safe evaluation of the non-safe analog sensors. The safety controller is preferably designed to initiate safety-related functions in the system to be monitored if the plausibility check shows that the safety integrity of the analog sensors is no longer ensured.

In one embodiment, it is proposed that the safety controller is designed to deactivate the working path of the first switching path during the test of the first sensing device. The test signal for the first analog sensor thus passes only through the test path of the first switching path. The working path is in an electrically blocked state.

In one embodiment, it is provided that the safety controller is designed to deactivate the working path of the second switching path during the test of the second sensing device. The test signal for the second analog sensor thus passes only through the test path of the second switching path. The working path is in an electrically blocked state.

In one embodiment, it is possible that the working path of the first sensing device comprises a normally closed contact, and the test path comprises a normally open contact and a resistor electrically connected in series therewith, so that the working path and the test path for the first sensing device have different resistance characteristics.

In one embodiment, it is proposed that the working path of the second sensing device comprises a normally closed contact and a resistor electrically connected in series therewith, and the test path comprises a normally open contact, so that the working path and the test path for the second sensing device have different resistance characteristics.

In an advantageous embodiment, it is provided that the safety controller is designed to test the first analog sensor and the second analog sensor alternately over time. These alternating tests have the advantage that, in particular, cable faults, cross faults, external voltage feeds, and faults to signal ground can be detected. In one embodiment, it is possible for the tests of the two analog sensors to be carried out continuously. This should be understood to mean that the analog sensors are continuously tested alternately during operation of the sensor system. Thus, while one of the two analog sensors is being tested, the other of the two analog sensors in each case measures the physical variable to be measured, such as the pressure.

Preferably, the safety controller may be designed to generate the test signals as square-wave pulses. As a result, testing of the two analog sensors alternating over time with high levels and low levels can be realized very easily in technical terms.

In one embodiment, it is possible that the safety controller comprises a first combined signal processing and test signal generating device, which is assigned to the first analog sensor, and/or that the safety controller comprises a second combined signal processing and test signal generating device, which is assigned to the second analog sensor.

In order to make it possible to distinguish between actual changes in the physical measured variable, in particular pressure changes within the system to be monitored, which lead to resistance changes in the sensing device, and a signal deviation due to a common cause of error (so-called common cause error), which may be, for example, electromagnetic interference or interference due to a resistance temperature drift, it is provided in an advantageous embodiment that the analog sensors are designed in such a way that they amplify the measurement signals to different degrees. Different amplifications may advantageously be realized, for example, by different k-factors of the two Wheatstone bridges. A k-factor is understood to mean a proportionality variable that represents the relationship between the measured mechanical deformation and the relative deformation of the respective sensing device. In other words, this means that the output signal of the Wheatstone bridges, from which the measurement signal of the analog sensor results, is stronger the greater the k-factor is. This means that the effect on the detectable signal deviation is different for both analog sensors and thus in both channels of the sensor system, and can therefore be detected by the safety controller. If the deviation is the same for both analog sensors, there is a change in the process value, for example, a change in pressure. If different changes are detected, on the other hand, there is a fault.

In a method according to the disclosure for testing a safety integrity of a sensor system, it is provided that:

for testing the first sensing device, the test path of the first switching path is closed, the first test signal is generated, and a resulting signal deviation of the measurement signal of the first analog sensor is detected,

for testing the second sensing device, the test path of the second switching path is closed, the second test signal is generated, and a resulting signal deviation of the measurement signal of the second analog sensor is detected, and

the signal deviation of the measurement signal of the first analog sensor and the signal deviation of the measurement signal of the second analog sensor are checked for plausibility by the safety controller.

The method according to the disclosure enables a safe evaluation of non-safe analog sensors in an advantageous way and thus the verification of the safety integrity of a sensor system, so that corresponding safety measures can be taken in the event of a fault.

In an advantageous embodiment, it is provided that the first analog sensor and the second analog sensor are tested alternately over time. This is an advantageous way to reliably detect cable faults, cross faults, external voltage feeds, and faults to signal ground, for example.

### BRIEF DESCRIPTION OF THE DRAWINGS

Further features and advantages of an exemplary embodiment of the disclosed system are described below with reference to the drawings.

FIG. 1 is a schematic representation illustrating the basic operating principle of a sensor system and of a method for checking the safety integrity of the sensor system.

FIG. 2 is a schematic representation of a first sensing device of the sensor system with an associated test switching path, which can be activated in a method for checking the safety integrity of the sensor system according to the present disclosure.

FIG. 3 is a schematic representation of a second sensing device of the sensor system with an associated switching path, which can be activated in the method for checking the safety integrity of the sensor system.

FIG. 4 is an exemplary test signal profile for checking the safety integrity of the analog sensors of the sensor system.

### DETAILED DESCRIPTION

It is not necessary for a sensor system 1 according to the disclosure to have all of the features described below. It is also possible for a sensor system 1 according to the disclosure to have only individual features of the exemplary embodiment described below.

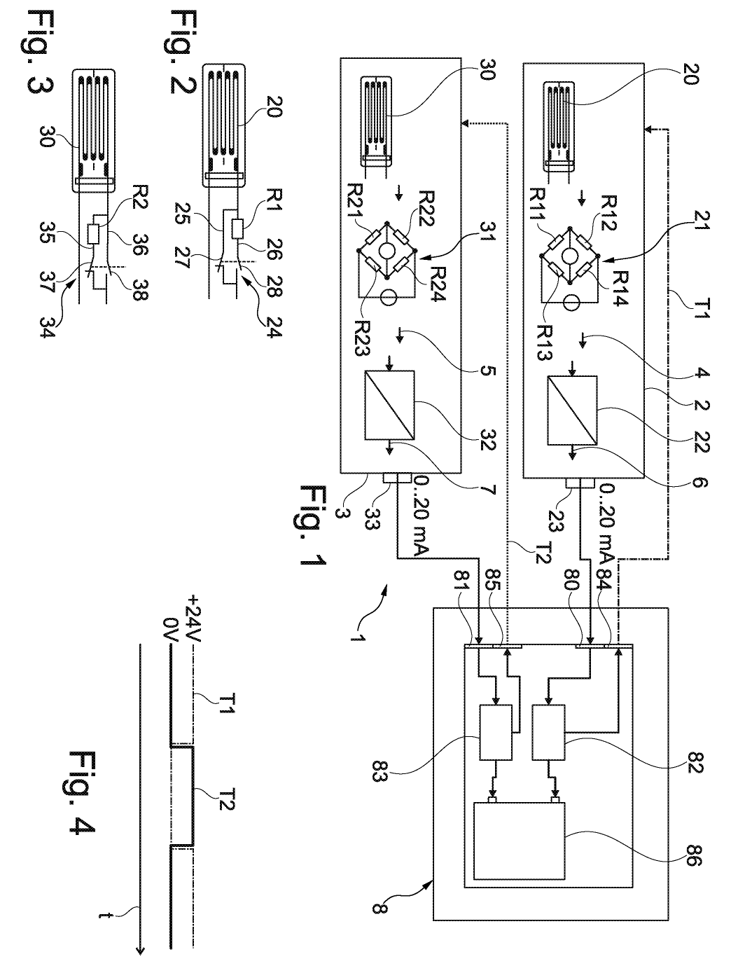

With reference to FIG. 1, the sensor system 1 comprises a first analog sensor 2 and a second analog sensor 3, each of which is designed as a single-channel sensor. The first analog sensor 2 comprises a first resistive sensing device 20 that is set up to measure a physical variable and has a variable electrical resistance. The second analog sensor 3 comprises a second resistive sensing device 30, which is set up to measure the same physical variable and has a variable electrical resistance. As a result of two analog sensors 2, 3 being provided, corresponding redundancy is obtained, which is particularly advantageous or may be absolutely necessary for safety-critical applications.

The sensor system 1 with the two analog sensors 2, 3 can be used in various process-related areas, for example, to detect pressures, temperatures, or leakages. To further explain the basic operating principle of the sensor system 1, it is assumed below that the two sensing devices 20, 30 are set up to measure pressures or pressure changes in a system to be monitored. The sensor system 1 is suitable, for example, for process applications such as hydrogen production, hydrogen storage, and the operation of hydrogen refueling systems for vehicles. In these applications, the prevailing pressures or pressure changes must be monitored so that suitable safety measures can be taken in the event of hazardous situations in order to prevent danger to people and the environment.

The sensing devices 20, 30 used in the sensor system 1 presented here are preferably designed as strain gauges for this aforementioned purpose. Strain gauges of this type are characterized by the fact that they change their electrical resistance in response to mechanical deformations caused by tensile strain or compressive strain. The analog sensors 2, 3 provided for pressure measurement typically comprise a pressure-resistant base body and a thin membrane, which are not shown in FIG. 1 for reasons of simplification. The membrane is equipped with the sensing devices 20, 30 designed as strain gauges, which are sensitive to tensile strain and compressive strain. The membrane deforms reversibly under the effect of pressure. This stretches or compresses the sensing devices 20, 30, which are applied to it as strain gauges, so that their electrical resistance changes.

In order to be able to measure the pressure-dependent resistance changes of the sensing devices 20, 30 designed as strain gauges in the event of pressure-dependent mechanical deformations, each of the two analog sensors 2, 3 respectively has a Wheatstone bridge 21, 31, which are operated in a known manner with a bridge supply voltage.

The first analog sensor 2 has a first Wheatstone bridge 21, which comprises the first sensing device 20 of the first analog sensor 2 designed in the form of a strain gauge and is designed to generate a first analog voltage signal 4, which is indicated by an arrow in FIG. 1, as an output signal. The first Wheatstone bridge 21 comprises a known bridge circuit arrangement with four electrical resistors R11, R12, R13, R14, wherein one of these resistors R11, R12, R13, R14 is formed by the variable electrical resistance of the first sensing device 20, which is designed as a strain gauge in the present case.

The second analog sensor 3 has a second Wheatstone bridge 31, which comprises the second sensing device 30 of the second analog sensor 3 and is designed to generate a second analog voltage signal 5 as an output signal. The second Wheatstone bridge 31 also comprises a bridge circuit arrangement with four electrical resistors R21, R22, R23, R24, wherein one of these resistors R21, R22, R23, R24 is formed by the variable electrical resistance of the second sensing device 30 designed as a strain gauge.

For example, in order to be able to measure pressures at different locations on the membrane or at one location on the membrane in different spatial directions, it is possible in principle for the analog sensors 2, 3 to comprise more than one resistive sensing device 20, 30, which are part of the first Wheatstone bridge 21 of the first analog sensor 2 or part of the second Wheatstone bridge 31 of the second analog sensor 3. In this context, embodiments having two or four sensing devices interconnected in the respective Wheatstone bridge 21, 31 are conceivable.

The two analog sensors 2, 3 also have a measurement signal converter 22, 32, which is designed to amplify the analog voltage signals 4, 5 of the Wheatstone bridges 21, 31. In the present case, the measurement signal converters 22, 32 are also designed to convert the analog voltage signals 4, 5 into analog current signals 6, 7. The analog current signals 6, 7 thus form the actual analog measurement signals of the analog sensors 2, 3 in this exemplary embodiment, which can be further processed and evaluated accordingly. In principle, the analog voltage signals 4, 5 of the Wheatstone bridges 21, 31 – possibly signal amplified – may also form the measurement signals of the analog sensors 2, 3.

The sensor system 1 also comprises a safety controller 8 with two signal inputs 80, 81. A first signal input 80 of the safety controller 8 is connected to a signal output 23 of the first analog sensor 2. A second signal input 81 of the safety controller 8 is connected to a signal output 33 of the second analog sensor 3. In this exemplary embodiment, the safety controller 8 comprises a first combined signal processing and test signal generating device 82 that which is assigned to the first analog sensor 2, and a second combined signal processing and test signal generating device 83 that is assigned to the second analog sensor 3.

The first combined signal processing and test signal generating device 82 is designed to receive and process the analog current signal 6, which forms the measurement signal of the first analog sensor 2, and in particular to detect a signal deviation generated during the test of the first sensing device 20. The first combined signal processing and test signal generating device 82 is further designed to generate a first test signal T1 for testing the first sensing device 20. The safety controller 8 has a first output 84 via which the first test signal T1 is transmitted to the first sensing device 20 during the execution of the test.

The second combined signal processing and test signal generating device 83 is designed to receive and process the analog current signal 7, which forms the measurement signal of the second analog sensor 3, and in particular to detect a signal deviation generated during the test of the second sensing device 30. The second combined signal processing and test signal generating device 83 is further designed to generate a second test signal T2 for testing the second sensing device 30. The safety controller 8 has a second output 85 via which the second test signal T2 is transmitted to the second sensing device 30.

In this exemplary embodiment, the signal processing and test signal generating functions are integrated into the first combined signal processing and test signal generating device 82 and into the second combined signal processing and test signal generating device 83. In principle, it is also possible to divide these functions into two functional components and to provide a first signal processing device and a first test signal generating device for the first analog sensor 2 and a second signal processing device and a second test signal generating device for the second analog sensor 3. However, the combined signal processing and test signal generating devices 82, 83 advantageously increase the degree of integration of the safety controller 8.

Furthermore, the safety controller 8 comprises an evaluation device 86, which is designed to safely evaluate the analog current signals (analog measurement signals) 6, 7 of the analog sensors 2, 3 processed by the two combined signal processing and test signal generating devices 82, 83 in the manner explained in more detail below. In particular, the evaluation device 86 is designed to evaluate the signal deviation that occurs during the test of the sensing devices 20, 30 of the two analog sensors 2, 3 and, in particular, to check its plausibility.

In the following, further details of a method for checking the safety integrity of the sensor system 1 described above will be explained in more detail, in which the non-safe sensing devices 20, 30 of the two analog sensors 2, 3 are tested via the two test signals T1, T2. To carry out the method, it is necessary that the sensing devices 20, 30 of the two analog sensors 2, 3 each be connected to an electrical switching path 24, 34, wherein each of the switching paths 24, 34 has a working path 25, 35 and a test path 26, 36 that are connected in parallel to one another. FIG. 2 shows the switching path 24 of the first sensing device 20 of the first analog sensor 2, and FIG. 3 shows the switching path 34 of the second sensing device 30 of the second analog sensor 3.

As can be seen in FIG. 2, the working path 25 of the first sensing device 20 of the first analog sensor 2 has a normally closed contact 27, which is in a closed position and thus electrically conductive during normal operation of the first sensing device 20, in which the pressure is measured and no safety integrity test is performed. The test path 26, which is connected in parallel to the working path 25, comprises a resistor R1 and a normally open contact 28 electrically connected in series with it, which is in an open position during normal operation of the first sensing device 20 and is thus electrically blocked. Actuation of the normally closed contact 27 and the normally open contact 28, which is triggered by the safety controller 8, takes place simultaneously. The normally closed contact 27 and the normally open contact 28 may, for example, be components of a relay, in particular of a solid-state relay. The functions of the normally closed contact 27 and of the normally open contact 28 may also be implemented by other electronic switching elements.

FIG. 3 shows that the working path 35 of the second sensing device 30 of the second analog sensor 3 comprises a normally closed contact 37, which is in a closed position during normal operation of the second sensing device 30, in which the pressure is measured and no safety integrity test is performed, and is thus electrically conductive, and a resistor R2 electrically connected in series with the normally closed contact 37. The test path 36, which is connected in parallel to the working path 35, comprises a normally open contact 38, which is in an open position during normal operation of the second sensing device 30 and is thus electrically blocked. Actuation of the normally closed contact 37 and the normally open contact 38, which is triggered by the safety controller 8, takes place simultaneously. The normally closed contact 37 and the normally open contact 38 may, for example, be components of a relay, in particular of a solid-state relay. The functions of the normally closed contact 37 and of the normally open contact 38 may also be implemented by other electronic switching elements.

The method presented here for checking the safety integrity of the two non-safe analog sensors 2, 3 is based on the principle of forced dynamization. The two analog sensors 2, 3 are each tested alternately over time using the associated test signal T1, T2. During the test, the switching elements, i.e., the NC contacts 27, 37 and the NO contacts 28, 38, in the switching paths 24, 34 of the two analog sensors 2, 3 are actuated by the safety controller 8 such that the respective NC contacts 27, 37 within the working path 25, 35 are opened so that they are subsequently electrically blocked, and at the same time the NO contacts 28, 38 of the test path 26, 36 are closed so that they are subsequently electrically conductive.

In the present case, the test signals T1, T2 are pulsed square-wave signals, the characteristics of which are shown by way of example in FIG. 4 as a function of time t. The pulsed square-wave test signals T1, T2 have a high level (in this case: + 24 V) and a low level (in this case: 0 V). In this exemplary embodiment, the pulse widths of the two test signals T1, T2 are identical. Furthermore, in this exemplary embodiment, the lengths of the pulse pauses also correspond to the pulse widths. Exemplary embodiments are also conceivable in which the pulse widths of the two test signals T1, T2 are selected differently and/or in which the lengths of the pulse pauses and the pulse widths are selected differently.

Due to the resistor R1 in the test path 26 for the first sensing device 20, there is an increase in resistance during the test as compared to normal operation, in which the current flows through the working path 25.

Due to the resistor R2 in the working path 35 and the absence of a resistor in the test path 36 for the second sensing device 30, there is a reduction in resistance as compared to normal operation during the test.

During the test phase, the Wheatstone bridge 21, 31 of the respective analog sensor 2, 3 is detuned. As a result, an increased or reduced signal deviation is generated in the time interval in which the respective test signal T1, T2 has a high level. This will be explained in more detail below. It should be assumed that a pressure of 100000 hPA (100 bar) prevails in the system to be monitored and that each of the two analog sensors 2, 3 outputs a current signal 6, 7 of 10 mA as the measurement signal during normal operation, which corresponds to the measured pressure.

When the test of the first sensing device 20 of the first analog sensor 2 is performed, a resistance increase occurs due to the resistor R1 in the test path 26 of the first sensing device 20, so that, for example, a first current signal 6 in the amount of 8 mA is output. This results in a negative signal deviation of -2 mA compared with the first current signal 6 in the amount of 10 mA in normal operation. Conversely, when the test of the second sensing device 30 is carried out, the resistance is reduced so that, for example, a second current signal 7 of 12 mA is output. This results in a positive signal deviation of +2 mA compared with the second current signal 7 in the amount of 10 mA during normal operation.

The corresponding signal deviations are recorded and processed by the first combined signal processing and test signal generating device 82 and the second signal processing device 83, and made available to the evaluation device 86 of the safety controller 8. The evaluation device 86 is designed to calculate the signal deviation from the current signals 6, 7 received and processed by the two combined signal processing and test signal generating devices 82, 83, which form the measurement signals and contain the corresponding signal deviations.

The expectation of the evaluation device 86 of the safety controller 8 is that the current signals 6, 7 must change by a defined value during the test of the respective analog sensor 2, 3 in a defined time interval, so that this results in a corresponding signal deviation. This makes it possible to check the plausibility of the measurement signals, i.e., the current signals 6, 7 of the two analog sensors 2, 3. As already explained, the two analog sensors 2, 3 are tested alternately over time. This alternating testing has the advantage that, in particular, cable faults, cross faults, external voltage feeds, and faults to signal ground can be detected.

To enable a distinction between actual pressure changes within the system to be monitored, which lead to resistance changes in the sensing devices 20, 30, and a signal deviation due to a common cause of error (so-called common cause error), which may be, for example, electromagnetic interference or interference due to a resistance temperature drift, it is advantageous to provide different amplification factors in both branches of the sensor system 1. These different amplification factors may advantageously be realized by different k-factors of the two Wheatstone bridges 21, 31. A k-factor is understood to be a proportionality variable that represents the relationship between the measured mechanical deformation and the relative deformation of the relevant sensing device 20, 30. In other words, this means that the greater the k-factor, the stronger the output signal of the Wheatstone bridges 21, 31 is. This means that the effect on the detectable signal deviation is different for both analog sensors 2, 3 and therefore in both channels of the sensor system 1 and can therefore be detected. If the deviation is the same, there is a process value change, in this case a pressure change. If different changes are detected, on the other hand, there is a fault.

The method described here advantageously enables a safe evaluation of the non-safe sensing devices 20, 30 of the two analog sensors 2, 3 and thus also a check of the safety integrity of the sensor system.

What is claimed is:

1. A sensor system, comprising:
a first analog sensor including: a first resistive sensing device configured to measure a physical variable, and a first Wheatstone bridge configured to generate a first analog voltage signal in response to the physical variable, the first analog sensor supplying a first measurement signal based on the first analog voltage signal, wherein the first resistive sensing device is connected to a first switching path including a first working path and a first test path connected in parallel with the first working path, the first test path having different resistance characteristics than the first working path;
a second analog sensor including: a second resistive sensing device configured to measure the physical variable, and a second Wheatstone bridge configured to generate a second analog voltage signal in response to the physical variable, the second analog sensor supplying a second measurement signal based on the second analog voltage signal, wherein the second resistive sensing device is connected to a second switching path including a second working path and a second test path connected in parallel with the second working path, the second test path having different resistance characteristics than the second working path; and
a safety controller connected to the first and second analog sensors to receive the first and second measurement signals, wherein the safety controller is configured to:
activate the first test path to test the first resistive sensing device, generate a first test signal, and detect a first signal deviation of the first measurement signal in response to the first test signal;
activate the second test path to test the second resistive sensing device, generate a second test signal, and detect a second signal deviation of the second measurement signal in response to the second test signal; and
check plausibility of the first and second signal deviations.

2. The sensor system of claim 1, wherein the safety controller is further configured to deactivate the first working path during testing of the first resistive sensing device.

3. The sensor system of claim 1, wherein the safety controller is further configured to deactivate the second working path during testing of the second resistive sensing device.

4. The sensor system of claim 1, wherein the first working path comprises a normally closed contact, and the first test path comprises a normally open contact and a resistor electrically connected in series therewith.

5. The sensor system of claim 1, wherein the second working path comprises a normally closed contact and a resistor electrically connected in series therewith, and the second test path comprises a normally open contact.

6. The sensor system of claim 1, wherein:
the first working path comprises a normally closed contact, and the first test path comprises a normally open contact and a first resistor electrically connected in series therewith; and
the second working path comprises a normally closed contact and a second resistor electrically connected in series therewith, and the second test path comprises a normally open contact.

7. The sensor system of claim 1, wherein the safety controller is further configured to test the first analog sensor and the second analog sensor alternately over time.

8. The sensor system of claim 1, wherein the safety controller is further configured to generate the first and second test signals as square-wave pulses.

9. The sensor system of claim 1, wherein the safety controller comprises at least one of:
a first combined signal processing and test signal generating device assigned to the first analog sensor; or
a second combined signal processing and test signal generating device assigned to the second analog sensor.

10. The sensor system of claim 1, wherein the first and second analog sensors are configured to respectively amplify the first and second measurement signals to different degrees.

11. A method for checking a safety integrity of the sensor system of claim 1, the method comprising:
testing the first resistive sensing device with the safety controller by: controlling the first switching path to activate the first test path, generating the first test signal, and detecting the first signal deviation of the first measurement signal;
testing the second resistive sensing device with the safety controller by: controlling the second switching path to activate the second test path, generating the second test signal, and detecting the second signal deviation of the second measurement signal; and
checking, with the safety controller, the first and second signal deviations for plausibility.
